(19) United States
(12) Patent Application Publication
(10) Pub. No.: US 2017/0256660 A1
(43) Pub. Date: Sep. 7, 2017

(54) SOLAR CELL AND SOLAR CELL MODULE

(71) Applicant: Panasonic Intellectual Property Management Co., Lt, Osaka (JP)

(72) Inventors: Satoshi Tohoda, Osaka (JP); Masao Kanda, Osaka (JP); Hiroki Yukawa, Osaka (JP)

(73) Assignee: Panasonic Intellectual Property Management Co., Ltd., Osaka (JP)

(21) Appl. No.: 15/601,325

(22) Filed: May 22, 2017

Related U.S. Application Data
(63) Continuation of application No. PCT/JP2015/005140, filed on Oct. 9, 2015.

(30) Foreign Application Priority Data
Nov. 28, 2014 (JP) 2014-242331

(51) Int. Cl. H01L 31/0376; H01L 31/075; H01L 31/0475

(52) U.S. Cl. CPC H01L 31/0376; H01L 31/0475; H01L 31/075

(57) ABSTRACT

A solar cell is provided with: an n-type single crystal silicon substrate; an n-type amorphous silicon layer disposed on a first main surface of the n-type single crystal silicon substrate; a light receiving surface electrode disposed on the n-type amorphous silicon layer; a p-type amorphous silicon layer disposed on a second main surface of the n-type single crystal silicon substrate; and a rear surface electrode disposed on the p-type amorphous silicon layer. The n-type single crystal silicon substrate has a resistivity within a range of 3.5-13 Ωcm. An i-type amorphous silicon layer may be provided between the n-type single crystal silicon substrate and the n-type amorphous silicon layer, and another i-type amorphous silicon layer may be provided between the n-type single crystal silicon substrate and the p-type amorphous silicon layer.

### CROSS-REFERENCE TO RELATED APPLICATION

The present application is a continuation under 35 U.S.C. §120 of PCT/JP2015/005140, filed Oct. 9, 2015, which is incorporated herein by reference and which claimed priority to Japanese Patent Application No. 2014-242331 filed November 28, 2014. The present application likewise claims priority under 35 U.S.C. §119 to Japanese Patent Application No. 2014-242331 filed Nov. 28, 2014, the entire content of which is also incorporated herein by reference.

### TECHNICAL FIELD

The present disclosure relates to a solar cell and a solar cell module.

### BACKGROUND

A solar cell is a device which includes a semi-conductor substrate in which a p-n junction is formed such that the p-n junction separates carriers generated in the semi-conductor substrate by incident light into holes and electrons so as to output photovoltaic power. A recombination center exists on surfaces of and inside the semi-conductor substrate. In this way, the carriers which have been generated by incident light are recombined and lost, lowering the output characteristics of the solar cell.

Regarding a photovoltaic element including an n-type single-crystal silicon substrate, an i-type amorphous silicon layer (i-type a-Si layer) and an n-type amorphous silicon layer (n-type a-Si layer) provided in this order between the n-type single-crystal silicon substrate and a light-receiving surface electrode, and an i-type amorphous silicon layer (i-type a-Si layer) and a p-type amorphous silicon layer (p-type a-Si layer) provided in this order between the n-type single-crystal silicon substrate and a rear surface electrode, Patent Literature 1 describes that the output characteristic of the photovoltaic element is enhanced because, when the p-type a-Si layer is disposed on the rear surface side, the amount of received light is not limited even if the p-type a-Si layer is thickened. Patent Literature 1 further describes that the carrier recombination due to the surface state of the crystal substrate can be prevented by thickening the i-type a-Si layer which is in contact with the p-type a-Si layer on the rear surface side.

### CITATION LIST

### Patent Literature

Patent Literature 1: JP 2006-237452 A

### SUMMARY

### Technical Problem

In a solar cell module, it is desired to suppress the decrease in the output characteristic due to carrier recombination.

### SUMMARY

### Solution to Problem

A solar cell according to the present disclosure includes an n-type crystal semiconductor substrate, an n-type amorphous semiconductor layer disposed on a first main surface of the n-type crystal semiconductor substrate, a light-receiving surface electrode disposed on the n-type amorphous semiconductor layer, a p-type amorphous semiconductor layer disposed on a second main surface of the n-type crystal semiconductor substrate, and a rear-surface electrode disposed on the p-type amorphous semiconductor layer. The n-type crystal semiconductor substrate has a resistivity within a range of 3.5 to 13 Ωcm.

In a solar cell module according to the present disclosure, a predetermined number of solar cells according to the present disclosure are connected to each other in series.

### Advantageous Effects of Invention

In a crystal semiconductor substrate, it is recognized that a higher resistivity reduces carrier recombination due to an impurity state inside a crystal. According to tests, short-circuit current values disperse when the resistivity of an n-type crystal semiconductor substrate is under 3.5 Ωcm, whereas the short-circuit current values are stable at a high level when the resistivity is within a range of 3.5 to 13 Ωcm.

As the n-type crystal semiconductor substrate has a resistivity within a range of 3.5 to 13 Ωcm according to the above configuration, the dispersion in the output characteristics of the solar cell can be reduced, suppressing the decrease in the output characteristics in the solar cell module.

### BRIEF DESCRIPTION OF DRAWINGS

FIG. 1 is a configuration diagram of a solar cell module according to an embodiment of the present disclosure;

FIG. 2 is a cross-sectional diagram of a solar cell according to an embodiment of the present disclosure;

FIG. 3 is a cross-sectional diagram of Part A in FIG. 1, wherein FIG. 3(a) is an overall view and FIG. 3(b) is a partial enlarged view;

FIG. 4 is a schematic diagram showing recombination of carriers in a solar cell according to an embodiment of the present disclosure;

FIG. 5 is a graph showing relationships between normalized short-circuit current values I_{sc} and resistivities of an n-type single-crystal silicon substrate in a solar cell according to an embodiment of the present disclosure;

FIG. 6 is a graph showing relationships between normalized open-circuit voltage values V_{oc} and resistivities of an n-type single-crystal silicon substrate in a solar cell according to an embodiment of the present disclosure; and

FIG. 7 is a graph showing relationships between normalized values of (short-circuit current value I_{sc} x open-circuit voltage value V_{oc}) based on FIGS. 6 and 7 and resistivities of an n-type single-crystal silicon substrate.

### DESCRIPTION OF EMBODIMENTS

Embodiments of the present disclosure are described in detail below with reference to the accompanying drawings. Specifics given below such as materials, thicknesses, sizes, numbers of solar cells, numbers of inter-cell wiring members, and numbers of solar cell strings are shown merely as examples for description. These specifics can be suitably changed in accordance with the specifications of the solar cell and the solar cell module. In the description below, the same reference numerals are used to denote corresponding elements throughout the drawings and redundant descriptions are omitted.

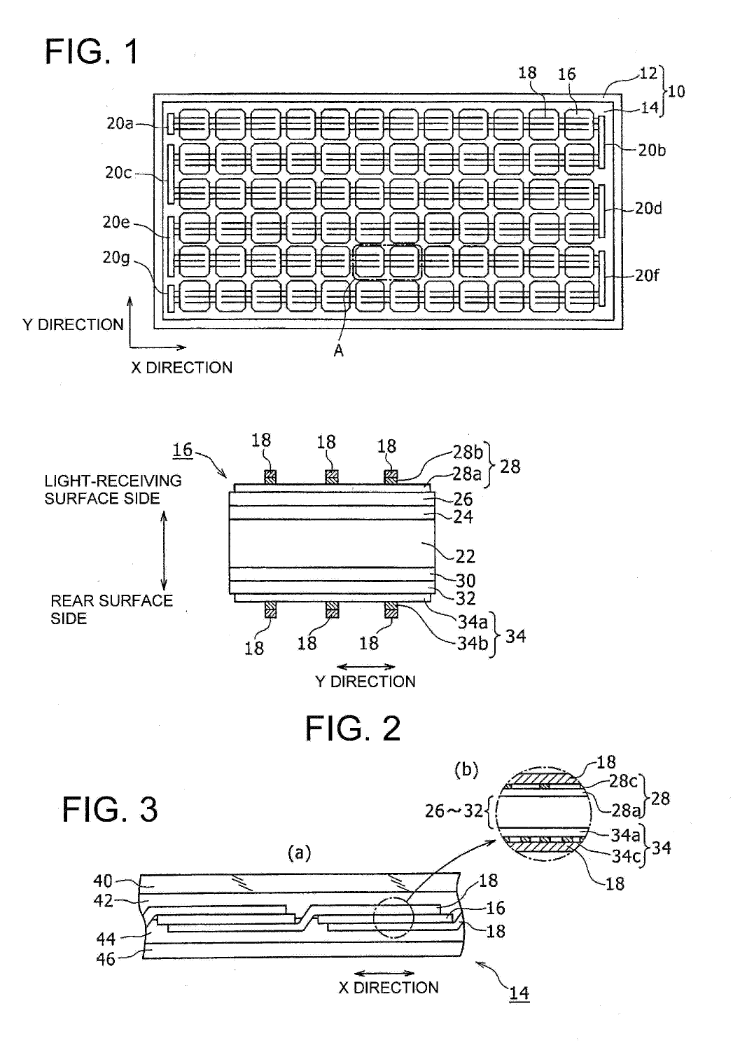

FIG. 1 is a plan view showing a configuration of a solar cell module 10. The solar cell module 10 is configured to include a laminate 14 and a frame 12 which supports end portions of the laminate 14. The laminate 14 includes a solar cell string group in which two or more solar cells 16 are connected in series. In the laminate 14, the solar cell string group is laminated with filling members and protective members such that the solar cell string group is sandwiched between a pair of the filling member and the protective member on the light-receiving surface side and a pair of the filling member and the protective member on the rear surface side. In the solar cell string group, two or more solar cell strings are connected to each other in series with connection wiring members 20a to 20g. In each solar cell string, two or more solar cells 16 are connected to each other in series with inter-cell wiring members. The inter-cell wiring members extend in the X direction and the connection wiring members 20a to 20g extend in the Y direction. The X direction and the Y direction are shown in FIGS. 1 to 3.

In an example shown in FIG. 1, a single solar cell string is formed by connecting twelve solar cells 16 to each other in series in the X direction with the inter-cell wiring members 18. Then, six solar cell strings are arranged horizontally from top to bottom in the Y direction. These six solar cell strings are connected to each other in series with the connection wiring members 20a to 20g to form a solar cell string group. In the solar cell string group, seventy-two (12×6) solar cells 16 are connected in series.

Each solar cell 16 includes a photoelectric conversion unit that generates carriers by receiving sunlight and an electrode that collects generated carriers. The photoelectric conversion unit includes a crystal semiconductor substrate of single-crystal silicon (c-Si), gallium arsenide (GaAs), and indium phosphorus (InP) or others and an amorphous semiconductor layer which is disposed on the crystal semiconductor substrate. The amorphous semiconductor layer is a non-crystallized semiconductor layer. In the description below, an n-type single-crystal silicon substrate is used as a crystal semiconductor substrate and an amorphous silicon layer as an amorphous semiconductor layer. Each electrode is formed to include a transparent conductive layer which is disposed on the amorphous silicon layer. The transparent conductive layer is a transparent conductive oxide including a metal oxide film of such as indium oxide (In₂O₃) and zinc oxide (ZnO) to which tin (Sn) or antimony (Sb) is doped.

FIG. 2 is a cross-sectional view of the solar cell 16. Each solar cell 16 includes an n-type single-crystal silicon substrate 22 (n-type c-Sᵢ layer). The thickness of the n-type single-crystal silicon substrate 22 is about 50 to 300 μm. As an example, the n-type single-crystal silicon substrate 22 of a thickness of about 150 μm is used.

The n-type single-crystal silicon substrate 22 contains phosphorus (P), which is an n-type dopant, at a predetermined concentration in a single-crystal silicon substrate. According to, for example, an American industry standard ASTM 723-99, the resistivity of an n-type single-crystal silicon substrate can be associated with the concentration of phosphorus (P), which is a dopant, at 1:1. Regarding the resistivity, the n-type single-crystal silicon substrate 22 having a resistivity of 3.5 to 13 Ωcm is used. The resistivity of 3.5 to 13 Ωcm corresponds to the concentration of phosphorus (P) of about 3.4×10¹⁴/cm³ to about 1.3×10¹⁵/cm³. It is more preferable to use the n-type single-crystal silicon substrate 22 having a resistivity of 5 to 13 Ωcm. The resistivity of 5 Ωcm corresponds to the concentration of phosphorus (P) of 9×10¹⁴/cm³. As the n-type single-crystal silicon substrate 22, a substrate to which a donor killing annealing process at about 600° C. or higher has been applied is used to suppress dispersion of the resistivity due to an oxygen donor effect. In this case, the concentration of oxygen which causes the emission of electrons is 0.1% or lower of all interstitial oxygen. Detailed description is provided below with reference to FIGS. 5 to 7.

As shown in FIG. 2, in each solar cell 16, amorphous silicon layers are formed respectively on the light-receiving surface side and the rear surface side. Specifically, an n-type amorphous silicon layer 26 and a light-receiving surface electrode 28 which is disposed on the n-type amorphous silicon layer 26 are laminated on a first major surface side, which is the light-receiving surface side of the n-type single-crystal silicon substrate 22. It is preferable to dispose an i-type amorphous silicon layer 24 between the n-type single-crystal silicon substrate 22 and the n-type amorphous silicon layer 26. A p-type amorphous silicon layer 32 and a rear surface electrode 34 which is disposed on the p-type amorphous silicon layer 32 are laminated on a second major surface side, which is the rear surface side of the n-type single-crystal silicon substrate 22. It is preferable to dispose an i-type amorphous silicon layer 30 between the n-type single-crystal silicon substrate 22 and the p-type amorphous silicon layer 32. It is preferable that a texture (not shown) is formed on the surface of the n-type single-crystal silicon substrate 22 such that the utilization efficiency of incident light can be enhanced with the uneven surface of the n-type single-crystal silicon substrate 22.

Configurations of the light-receiving surface electrode 28 and the rear surface electrode 34 are described below by referring to FIGS. 2 and 3. FIG. 3 shows arrangement of the inter-cell wiring members 18. FIG. 3(a) shows the entire configuration and FIG. 3(b), which is a partial enlarged view, shows detailed configuration of the light-receiving surface electrode 28 and the rear surface electrode 34.

The light-receiving surface electrode 28 is configured to include a transparent conductive layer 28a which is disposed on the n-type amorphous silicon layer 26 and light-receiving surface current collectors 28b, 28c which are disposed on the transparent conductive layer 28a. The light-receiving surface current collector 28b is a busbar electrode which is connected to the inter-cell wiring member 18. The light-receiving surface current collector 28c is a finger electrode which extends perpendicular to the busbar electrode and has a width thinner than the busbar electrode. Similarly, the rear surface electrode 34 is configured to include a transparent conductive layer 34a, which is disposed on the p-type amorphous silicon layer 32 and rear surface current collectors 34b, 34c which are disposed on the transparent conductive layer 34a. The rear surface current collector 34b is a busbar electrode which is connected to the inter-cell wiring member 18. The rear surface current collector 34c is a finger electrode which extends perpendicular to the busbar electrode and have a width thinner than the busbar electrode.

Because light enters on the light-receiving surface side, it is desirable that the area of the n-type amorphous silicon layer 26 covered by the light-receiving surface current collectors 28b, 28c is as small as possible. Thus, a wide interval is provided between the finger electrodes on the light-receiving surface side. As the rear surface side is not the light incident side, such restrictions are not required. The interval between the finger electrodes on the rear surface side may therefore be narrow. The rear surface current collectors 34b, 34c may be provided to almost entirely cover the rear surface side. Such light-receiving surface current collectors 28b, 28c and the rear surface current collectors 34b, 34c can be obtained by printing predetermined patterns with conductive paste or other materials.

The amorphous silicon layers are required to have a thickness sufficient to eliminate the surface state of the n-type single-crystal silicon substrate 22. For example, the n-type amorphous silicon layer 26 may have a thickness of about 3 nm to about 10 nm, the p-type amorphous silicon layer 32 may have a thickness of about 5 nm to about 30 nm, and the i-type amorphous silicon layers 24, 30 may have a thickness of about 3 nm to about 80 nm.

When using the n-type single-crystal silicon substrate 22 having a resistivity within a range of 3.5 to 13 Ωcm, it is preferable for easy carrier movement in the plane direction of the n-type single-crystal silicon substrate 22 (XY plane direction in FIG. 1) that the transparent conductive layers 28a, 34a be provided such that the sheet resistance of the transparent conductive layers 28a, 34a, including the resistance of the n-type single-crystal silicon substrate 22, is from 50 to 90 Ωcm. In this case, the transparent conductive layers 28a, 34a have a thickness from 55 nm to 86 nm on the n-type single-crystal silicon substrate 22 on which a texture is formed.

It is further preferable that the light-receiving surface current collectors 28c be disposed at a pitch from 1.5 mm to 2.5 mm. In a configuration in which the rear surface current collector is provided with the busbar electrode and the finger electrode, a preferable pitch between the rear surface current collectors 34c is from 0.1 to 2.5 mm. In this case, it is preferable that the light-receiving surface current collectors 28c and the rear surface current collectors 34c have a resistance of 25 to 100 mΩ per length of 1 mm. In this way, the carrier loss can be further reduced and the dispersion in short-circuit current values I_{SC} can be suppressed.

It should be noted that the solar cell 16 is not limited to this configuration. For example, the i-type amorphous silicon layers 24, 30 may be omitted in some cases. Further, the rear surface electrode 34 may be configured to have a larger area than the light-receiving surface electrode 28.

The inter-cell wiring members 18 are conductors which are disposed on both of the light-receiving surface electrode 28 and the rear surface electrode 34 to connect the adjacent solar cells 16 in series along the X direction. A method to connect the adjacent solar cells 16 by using the inter-cell wiring members 18 is described below with reference to FIG. 3. FIG. 3 is a cross-sectional diagram of two solar cells 16 in Part A in FIG. 1, along the X direction

Each inter-cell wiring member 18 is formed with two types of wiring members. Of the twelve solar cells 16 arranged in the X direction to form a solar cell string, three adjacent solar cells (a first solar cell, a second solar cell, and a third solar cell) are described. The wiring member of one of the two types connects between a light-receiving surface electrode of the second solar cell and a rear surface electrode of the first solar cell. The other type connects between a rear surface electrode of the second solar cell and a light-receiving surface electrode of the third solar cell. A solar cell string in which twelve solar cells 16 are connected in series is formed by repeating such connections. Each solar cell 16 is sandwiched between an inter-cell wiring member 18 connected to the light-receiving surface electrode and another inter-cell wiring member 18 connected to the rear surface electrode.

In FIG. 3, the solar cell 16 on the left in the X direction is the first solar cell 16, whereas the solar cell 16 on the right is the second solar cell 16. Although the third solar cell 16 described above is omitted, the third solar cell 16 is positioned on the right of the second solar cell 16. Three inter-cell wiring members 18 are connected on both of the right-receiving surface and the rear surface of the solar cell 16.

As the inter-cell wiring member 18, a thin plate formed of a metal conductive material such as copper is used. In place of the thin plate member, a twisted string member may be used. As the metal conductive material, besides copper, materials such as silver, aluminum, nickel, tin, gold, and their alloys may be used.

The inter-cell wiring members 18 are connected to the light-receiving surface electrode 28 and the rear surface electrode 34 of the solar cells 16 by soldering or using adhesive. As the adhesive, acrylic resin, highly elastic polyurethane resin, or thermosetting resin adhesive such as epoxy resin may be used. The adhesive contains conductive particles. As the conductive particles, nickel, silver, nickel with gold coating, copper with tin plating, or other materials may be used. An insulating resin adhesive may be used as the adhesive. For example, for the light-receiving surface of the solar cell 16, the electrical connection can be achieved by forming a region where the inter-cell wiring member 18 and the light-receiving surface electrode 28 are in direct contact with each other.

Referring back to FIG. 1, the connection wiring members 20a to 20g respectively connect between adjacent solar cell strings among the six solar cell strings which are formed with the inter-cell wiring members 18. As the material of the connection wiring members 20a to 20g, any of the materials described above as the material of the inter-cell wiring member 18 may be used. The connection wiring members 20a to 20g are disposed on both ends in the X direction outside the region where the six solar cell strings are disposed.

In the example shown in FIG. 1, the six solar cell strings are connected in series in the following order to form a solar cell string group in which the total of 72 solar cells 16 are connected in series: the connection wiring member 20a, (the solar cell string disposed on the top in the Y direction), the connection wiring member 20b, (the solar cell string disposed second from the top), the connection wiring member 20c, (the solar cell string disposed third from the top), the connection wiring member 20d, (the solar cell string disposed forth from the top), connection wiring member 20e, (the solar cell string disposed fifth from the top), the connection wiring member 20f, (the solar cell string disposed sixth from the top, or at the bottom in the Y direction), and the connection wiring member 20g.

In the laminate 14, the elements are laminated in the following order: a first protective member 40 on the light-receiving surface side, a first filling member 42 on the light-receiving surface side, the solar cell string group, a second filling member 44 on the rear surface side, and a second protective member 46 on the rear surface side. The elements in the laminate 14 will be described with reference to FIG. 3. FIG. 3 shows two solar cells 16 as a part of the solar cell string.

The first protective member 40 is a protective member on the light-receiving surface side in the solar cell module 10. In order to allow light to enter the solar cells 16, the first protective member 40 is formed with a transparent member. Although a glass substrate, a resin substrate, a resin film, and others are available as the transparent member, the glass substrate is preferable in consideration of properties such as fire resistance and durability. The glass substrate may have a thickness of about 1 to 6 mm.

The first filling member 42 fills a gap between the solar cell string group and the first protective member 40 to seal the solar cell string group. As the first filling member 42, a transparent filling member such as a polyethylene-based olefin resin and ethylene vinyl acetate (EVA) may be used. Besides EVA, materials such as ethylene ethyl acrylate (EEA), polyvinyl butyral (PVB), a silicone resin, a urethane resin, an acrylic resin, and an epoxy resin may be used.

The second filling member 44 fills a gap between the solar cell string group and the first protective member 40 to seal the solar cell string group. As the second filling member 44, a transparent filing member as for the first filling member 42 may be used. In this case, a resin of the same material as for the first filling member 42 may be used.

Depending on the specifications of the solar cell module 10, a colored filling member may be used. As the colored filing member, the above-described colorless transparent filling member to which an inorganic pigment such as titanium oxide or zinc oxide is added as an additive to turn the color to white may be used.

As the second protective member 46, an opaque plate or film may be used to prevent the light which has passed through the second filling member 44 from leaking to the outside. For example, a laminate film such as a resin film in which an aluminum foil is disposed inside may be used. Depending on the specifications of the solar cell module 10, the second protective member 46 may be a transparent sheet to transmit the light which has passed through the second filling member 44 to the outside from the rear surface side.

The two output terminals of the solar cell module 10 are the connection wiring member 20a and the connection wiring member 20g. The voltage value between these output terminals obtained when light enters the light-receiving surface of the solar cell module 10 and the output terminals of the solar cell module 10 are both disconnected is the open-circuit voltage value V_{oc} of the solar cell module 10. The current value which is output between these output terminals when the output terminals of the solar cell module 10 are both short-circuited is the short-circuit current value I_{sc} of the solar cell module 10.

The output characteristics of the solar cells 16 are dispersed in some degrees. The solar cell module 10 is formed by connecting 72 solar cells 16 in series. As the open-circuit voltage value V_{oc} of the solar cell module 10 is the total of the respective open-circuit voltage values of the 72 solar cells 16, there is no reduction in output due to the dispersion in the output characteristics. In contrast, because the short-circuit current value I_{sc} of the solar cell module 10 is limited to the short-circuit current value I_{sc} of the solar cells 16 having the lowest short-circuit current value I_{sc}, a drop in the short-circuit current value I_{sc} and the output power value (Pmax) of the solar cell module 10 may be caused due to the dispersion in the short-circuit current value I_{sc} of the solar cell module 10.

The short-circuit current value I_{sc} is low when the number of carrier recombinations is high. The carriers generated in the solar cells 16 are recombined on the surface of or inside the n-type single-crystal silicon substrate 22. As described in Patent Literature 1, in the solar cells 16 using the n-type single-crystal silicon substrate 22, the carrier recombination caused by the surface state of the surface of the n-type single-crystal silicon substrate 22 can be prevented by disposing an amorphous silicon layer between the n-type single-crystal silicon substrate 22 and the light-receiving surface electrode 28 and between the n-type single-crystal silicon substrate 22 and the rear surface electrode 34. Further, inside the n-type single-crystal silicon substrate 22, the recombination can be prevented by reducing the impurity state or other factors.

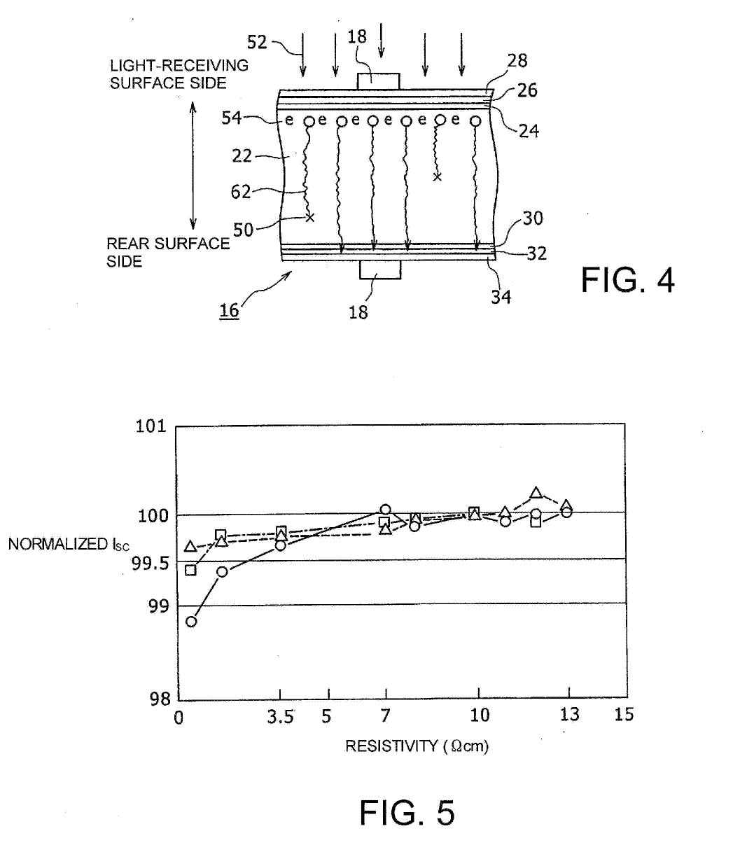

In an impurity state 50 located inside a crystal of the n-type single-crystal silicon substrate 22, because substances such as iron (Fe), copper (Cu), nickel (Ni) are present inside the crystal of the n-type single-crystal silicon substrate 22, these substances form the center of the recombination of electrons and holes, which are carriers. As shown in FIG. 4, carriers are generated in the vicinity of the interface on the light-receiving surface side of the n-type single-crystal silicon substrate 22 due to incident light 52 which enters on the right-receiving surface side of the solar cells 16.

Electrons 54 and holes 56, which are carriers, are generated in the vicinity of the interface on the light-receiving surface side of the n-type single-crystal silicon substrate 22. The electrons 54 move towards the light-receiving surface electrode 28, whereas the holes 56 move towards the rear surface electrode 34.

Because electrons are the majority carrier of the n-type single-crystal silicon substrate 22, the electrons 54 can be easily collected by the light-receiving surface electrode 28.

Because the holes 56 generated in the n-type single-crystal silicon substrate 22 are the minority carrier, the holes 56 cannot be collected as easily as the electrons 54.

Specifically, the holes 56 generated in the vicinity of the interface on the light-receiving surface side of the n-type single-crystal silicon substrate 22 are required to travel the distance equal to the thickness of the n-type single-crystal silicon substrate 22. In other words, because the holes 56 are required to travel a longer distance inside the n-type single-crystal silicon substrate 22 than the electrons 54, the occurrences of recombination inside the n-type single-crystal silicon substrate 22 will increase. When the holes 62 captured in the impurity state or the like recombine with the majority carrier electrons of the n-type single-crystal silicon substrate 22 and vanish, and the holes 62 cannot reach the p-type amorphous silicon layer 32.

As described above, for the solar cell 16 which includes the p-type amorphous silicon layer 32 on the rear surface side of the n-type single-crystal silicon substrate 22, there are many occasions when the holes 56 generated by the incident light 52 vanish due to recombination inside the crystal of the n-type single-crystal silicon substrate 22. Therefore, the short-circuit current value I_{sc} that can be obtained when the light-receiving surface electrode 28 and the rear surface electrode 34 are short-circuited is likely to be low.

In a solar cell having a heterojunction in which the p-type amorphous silicon layer 32 and the n-type amorphous silicon layer 26 are used as dope layers, it is required to move the carriers in the plane direction (X-Y plane direction in FIG. 1) of the n-type single-crystal silicon substrate 22. Therefore, in consideration of the movement of the carriers in the plane direction, it is better if the resistance of the n-type single-crystal silicon substrate 22 is low. However, it has been found that the carrier recombination causes dispersion in the short-circuit current values I_{sc}, lowering the output of the module.

As shown in the comparative example in Patent Literature 1, for a solar cell which includes a p-type amorphous silicon layer on the light-receiving surface side, because carriers are generated in vicinity of the p-type amorphous silicon layer, the distance for which a hole travels is short. In this way, in the solar cell which includes the p-type amorphous silicon layer on the light-receiving surface side, effects caused by the decline in the short-circuit current value I_{sc} which can be obtained when the light-receiving surface electrode 28 and the rear surface electrode 34 are short-circuited is low.

It should be noted here that in a crystal semiconductor substrate, the recombination is suppressed more than when the resistivity is higher. This may be because when the resistivity is high, the impurities inside the crystal are reduced and the effect of Auger recombination becomes lower due to a lower number of majority carriers. Therefore, the decline in the short-circuit current value I_{sc} due to recombination inside the crystal of the n-type single-crystal silicon substrate 22 can be assumed to be suppressed, by setting the resistivity of the n-type single-crystal silicon substrate 22 to a value in a sufficiently high range.

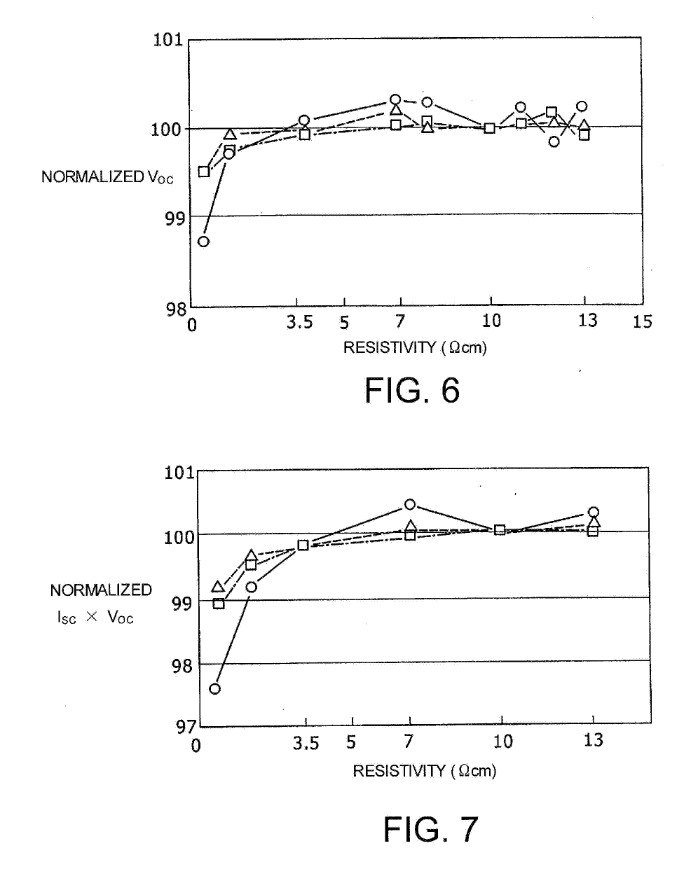

FIGS. 5 to 7 show changes, confirmed in tests, in the short-circuit current values I_{sc}, open-circuit voltage values V_{oc}, and values of output power (short-circuit current value I_{sc} x open-circuit voltage value V_{oc}) along with changes in the resistivity of the n-type single-crystal silicon substrate 22. In these drawings, the horizontal axis represents the resistivity of the n-type single-crystal silicon substrate 22. The vertical axis in FIG. 5 represents normalized short-circuit values I_{sc}, the vertical axis in FIG. 6. represents normalized open-circuit values V_{oc}, and the vertical axis in FIG. 7 represents normalized values of output power (short-circuit current value I_{sc} x open-circuit voltage value V_{oc}). The normalization was applied such that the value obtained at the resistivity of 10 Q cm was assumed to be 100. For each drawing, tests were performed for three times. Each test result is shown with white circles (O), white triangles (Δ) and white squares (□).

FIG. 5 is a graph showing a relationship between the resistivity of the n-type single-crystal silicon substrate 22 and the normalized short-circuit value I_{sc} of the solar cells 16. As shown in FIG. 5, the normalized short-circuit current value I_{sc} was almost stable in a high range of the resistivity. The normalized short-circuit current value I_{sc} dispersed more along the transition of the resistivity from a high resistivity to a low resistivity.

The short-circuit current value I_{sc} of the solar cell module 10 is determined by the short-circuit current value I_{sc} of the solar cell which has the lowest short-circuit current value among the 72 solar cells 16. Reduction in output of the solar cell module 10 can be suppressed by reducing the dispersion in the short-circuit current values I_{sc} of the solar cells 16 which form the solar cell module 10. Specifically, the resistivity of the n-type single-crystal silicon substrate 22 is preferably set at a high value.

As a result shown in FIG. 5, for example, in order to keep the dispersion in the short-circuit current values I_{sc} of the solar cell module 10 within 0.5%, it is preferable to set the resistivity of the n-type single-crystal silicon substrate 22 of the solar cells 16 used for the solar cell module 10 to 3.5 Ωcm or higher. The upper limit is preferable to be set at the upper limit in the tests, which is 13 Ωcm. Therefore, by setting the resistivity of the n-type single-crystal silicon substrate 22 of the solar cells 16 within a range of 3.5 Ωcm to 13 Ωcm, the dispersion in the short-circuit current values I_{sc} of the solar cell module 10 can be reduced in comparison with when the resistivity is set to be lower than 3.5 Ωcm.

When the resistivity is set at 7 Ωcm or higher, almost no dispersion is found in the short-circuit current values I_{sc} of the respective solar cells 16. When the resistivity reaches over 5 Ωcm, for example, 7 Ωcm, the short-circuit current values I_{sc} are converged. Therefore, by setting the resistivity to 5 Ωcm to 13 Ωcm, the dispersion in the short-circuit current values I_{sc} of the solar cell module 10 can be reduced.

FIG. 6 is a graph showing a relationship between the resistivity of the n-type single-crystal silicon substrate 22 and the normalized open-circuit voltage value V_{oc} of the solar cells 16. As shown in FIG. 6, the normalized open-circuit voltage values V_{oc} were almost stable in a high range of the resistivity. The normalized open-circuit voltage value V_{oc}=100 when the substrate resistivity is 10 Ωcm. The normalized open-circuit voltage value V_{oc} reaches a maximum value within a range of about 7 Ωcm along with the transition of the resistivity from a high resistivity to a low resistivity. Then, after being almost stable as the resistivity transits from a high resistivity to a low resistivity, the value gradually drops to a lower value and the dispersion, including the dispersion among the tests, becomes larger. Similarly as shown in FIG. 5, by setting the resistivity of the n-type single-crystal silicon substrate 22 of the solar cells 16 within a range of 3.5 Ωcm to 13 Ωcm, the dispersion in the open-circuit voltages values I_{oc} of the solar cell module 10 can be reduced more than when the resistivity is set lower than 3.5 Ωcm.

FIG. 7 is a graph showing a relationship between the value of (normalized short-circuit current value I_{sc}×normalized open-circuit voltage value V_{oc}) of the solar cells 16 obtained by using the results shown in FIGS. 5 and 6 and the resistivity of the n-type single-crystal silicon substrate 22. It is obvious from FIG. 7 that the value of (normalized short-circuit current value I_{sc}×normalized open-circuit voltage value V_{oc}) reaches the maximum value when the resistivity is within a range of 3.5 Ωcm to 13 Ωcm, whereas the value is lower than the maximum value and dispersion becomes larger when the resistivity is below 3.5 Ωcm. When the resistivity reaches over 5 Ωcm, for example, 13 Ωcm, the values of (normalized short-circuit current value I_{sc}×normalized open-circuit voltage value V_{oc}) are converged. Therefore, by setting the resistivity to 5 Ωcm to 13 Ωcm, the value of (normalized short-circuit current value I_{sc}×normalized open-circuit voltage value V_{oc}), which is an index regarding the amplitude of fill factor of the solar cell module 10, can be kept in a range suitable for a practical use.

Based on the results shown in FIGS. 5 to 7, a decline in output of the solar cell module 10 can be suppressed by using the solar cells 16 whose n-type single-crystal silicon substrates 22 have a resistivity within a range of 3.5 Ωcm to 13 Ωcm and by forming the solar cell module 10 with a predetermined number of solar cells 16 connected in series. It is preferable to set the resistivity of the n-type single-crystal silicon substrate 22 within a range of 5 Ωcm to 13 Ωcm. The resistivity of the n-type single-crystal silicon substrate 22 can be kept in a predetermined range by adjusting the concentration of phosphorus (P), which is an n-type dopant.

By setting the phosphorus concentration of the n-type single-crystal silicon substrate 22 to 3.4×10¹⁴/cm³14 to 1.3×10¹⁵/cm³, the resistivity within a range of 3.5 Ωcm to 13 Ωcm can be obtained. Further, by setting the phosphorus concentration of the n-type single-crystal silicon substrate 22 to 3.4×10¹⁴/cm³ to 9×10¹⁴/cm³, the resistivity within a range of 5 Ωcm to 13 Ωcm can be obtained.

The n-type single-crystal silicon substrate 22 contains interstitial oxygen atoms at a concentration of 1×10¹⁷ atoms/cm³ to 1×10¹⁸ atoms/cm³. It is well-known that the interstitial oxygen in a silicon crystal forms a thermal donor and emits electrons in a certain temperature range. Therefore, the amount of electrons emitted from the interstitial oxygen varies in a thermal process, resulting in dispersion in the resistivity. Because the control of the resistivity by the thermal donors is unstable, the dispersion in the resistivity can be suppressed by reducing the oxygen concentration, which causes the emission of electrons, to 0.1% or lower of all interstitial oxygen. It is more preferable to reduce the oxygen concentration to 0.001% or lower to reduce the dispersion in the resistivity.

Holes recombine inside the n-type single-crystal silicon substrate 22. By making the n-type single-crystal silicon substrate 22 thin, the distance that the holes are required to travel can be shortened, further suppressing the recombination of holes. By making the n-type single-crystal silicon substrate have a thickness of 150 μm or thinner, the recombination of holes can be suppressed. It is more preferable to make the thickness 120 μm or thinner to further suppress the recombination of holes.

Further, by reducing the surface state, the recombination of carriers inside the n-type single-crystal silicon substrate 22 can be suppressed. By reducing interface defects on the light-receiving surface, because a longer carrier life time can be obtained, the recombination of carriers can be further suppressed. The recombination of carriers can be suppressed by setting the open-circuit voltage value V_{oc} to 0.7V or higher. It is more preferable to set the open-circuit voltage value to 0.72 V or higher to further suppress the recombination of holes.

### INDUSTRIAL APPLICABILITY

The present invention can be used for a solar cell and a solar cell module.

### REFERENCE NUMERALS

10 solar cell module, 12 frame, 14 laminate, 16 solar cells, 18 inter-cell wiring member, 20a, 20b, 20c, 20d, 20e, 20f, 20g connection wiring members, 22 n-type single-crystal silicon substrate (n-type semiconductor substrate), 24, 30 i-type amorphous silicon layers (i-type amorphous semiconductor layers), 26 n-type amorphous silicon layer (n-type amorphous semiconductor layer), 28 light-receiving surface electrode, 28a, 34a transparent conductive layers, 28b, 28c light-receiving surface current collectors, 32 p-type amorphous silicon layer (p-type amorphous semiconductor layer), 34 rear surface electrode, 34b, 34c rear surface current collectors, 40 first protective member, 42 first filling member, 44 second filling member, 46 second protective member, 50 impurity state, 52 incident light, 54 electrons, 56, 62 holes, and 58, 60 distance.

1. A solar cell comprising:
an n-type crystal semiconductor substrate;
an n-type amorphous semiconductor layer disposed on a first main surface of the n-type crystal semiconductor substrate;
a light-receiving surface electrode disposed on the n-type amorphous semiconductor layer;
a p-type amorphous semiconductor layer disposed on a second main surface of the n-type crystal semiconductor substrate; and
a rear surface electrode disposed on the p-type amorphous semiconductor layer,
wherein the n-type crystal semiconductor substrate has a resistivity within a range of 3.5 to 13 Ωcm.

2. The solar cell according to claim 1, wherein
the n-type crystal semiconductor substrate contains phosphorus as an n-type dopant; and
a concentration of the phosphorus in the n-type crystal semiconductor substrate is 3.4×10¹⁴/cm³ to 1.3×10¹⁵/cm³.

3. The solar cell according to claim 1, wherein
the n-type crystal semiconductor substrate has a resistivity within a range of 5 to 13 Ωcm.

4. The solar cell according to claim 3, wherein
the n-type crystal semiconductor substrate contains phosphorus as an n-type dopant; and
a concentration of the phosphorus of the n-type crystal semiconductor substrate is 3.4×10¹⁴/cm³ to 9×10¹⁴/cm³.

5. The solar cell according to claim 1, wherein
a concentration of oxygen which causes emission of electrons of the n-type crystal semiconductor substrate is 0.1% or lower of all interstitial oxygen.

6. The solar cell according to claim 1, wherein the n-type crystal semiconductor substrate has a thickness of 50 μm to 150 μm.

7. The solar cell according to claim 1, wherein an i-type amorphous semiconductor layer is disposed between the n-type crystal semiconductor substrate and the n-type amorphous semiconductor layer; and
another i-type amorphous semiconductor layer is disposed between the n-type crystal semiconductor substrate and the p-type amorphous semiconductor layer.

8. A solar cell module wherein a predetermined number of the solar cells according to claim 1 are connected to each other in series.
